(19) United States
(12) Patent Application Publication
(10) Pub. No.: US 2011/0197952 A1
(43) Pub. Date: Aug. 18, 2011

(54) PHOTOVOLTAIC DEVICE AND MANUFACTURING METHOD FOR A PHOTOVOLTAIC DEVICE

(75) Inventors: Toshie Kunii, Gifu (JP); Shigeo Yata, Gifu (JP)

(73) Assignee: Sanyo Electric Co., Ltd, Moriguchi-shi, OSAKA (JP)

(21) Appl. No.: 13/121,797

(22) PCT Filed: Nov. 25, 2009
(86) PCT No.: PCT/JP2009/069838

§ 371 Date: Mar. 30, 2011

(30) Foreign Application Priority Data
Dec. 9, 2008 (JP) 2008-313001

(51) Int. Cl. H01L 31/0224; H01L 31/18

(52) U.S. Cl. 136/249; 438/73; 257/E31.126

(57) ABSTRACT

A photovoltaic device has a first photovoltaic cell unit and a second photovoltaic cell unit stacked on either side of a conductive intermediate layer, between a first electrode and a second electrode, the first electrode and second electrode being electrically connected by a channel formed through the first photovoltaic cell unit, the second photovoltaic cell unit, and the intermediate layer as far as the surface of the first electrode, and a PN junction being formed at an end section of the intermediate layer that contacts the second electrode by adding dopant.

### BACKGROUND OF THE INVENTION

1. Field of the Invention

The present invention relates to a photovoltaic device and a manufacturing method for a photovoltaic device.

2. Description of the Related Art

As shown in FIG. 3, a tandem type photovoltaic device having upper and a lower photovoltaic cell units 10, 12 stacked on either side of an intermediate layer 14 is known. One or more types of transparent conductive film are used in the intermediate layer 14 interposed between the upper and lower photovoltaic cell units. Also, a rear surface electrode 18 of silver (Ag) for also serving as a rear surface reflective layer is formed on part of the rear surface electrode, and the rear surface electrode 18 is connected to a front surface electrode 16 by means of a channel D formed penetrating through as far as the front surface electrode 16.

With this type of structure, the intermediate layer 14 interposed between the upper and lower photovoltaic cell units 10, 12 is in partial contact with the rear surface electrode 18 by means of the channel D. If the intermediate layer 14 and the rear surface electrode 18 are in electrical contact, current leakage will occur at the point of their electrical contact, and the electrical generation characteristics of the photovoltaic device will be lowered.

Technology has therefore been disclosed to control current leakage with increase in oxygen content close to end sections of the intermediate layer 14, by eliminating the photovoltaic cell units 10, 12 using a laser beam in an oxidizing atmosphere when forming the channel D (patent document 1 etc.).

Patent Document 1: Japanese Patent Laid-open No. Hei 7-114292

However, when carrying out laser processing in an oxidizing atmosphere the photovoltaic cell units, which are electricity generating layers, are exposed to oxygen, and a new problem arises in that the characteristics of the photovoltaic cell units themselves are lowered.

In view of the above described situation, the present invention has as its object to provide a photovoltaic device that suppresses reduction in characteristics due to contact between an intermediate layer and a rear surface electrode, without degrading characteristics of a photovoltaic cell unit, and a manufacturing method for such a photovoltaic device.

### SUMMARY OF THE INVENTION

A first aspect of the present invention is a photovoltaic device with a first photovoltaic cell unit and a second photovoltaic cell unit stacked on either side of a conductive intermediate layer, between a first electrode and a second electrode, wherein the first electrode and second electrode are electrically connected by a channel formed through the first photovoltaic cell unit, the second photovoltaic cell unit and the intermediate layer as far as the surface of the first electrode, and a PN junction is formed at an end section of the intermediate layer that contacts the second electrode by adding dopant.

Another aspect of the present invention is a photovoltaic device having a first electrode, a first photovoltaic cell unit, a conductive intermediate layer, a second photovoltaic cell unit and a second electrode sequentially stacked, wherein the first electrode and second electrode are electrically connected by a channel formed through the first photovoltaic cell unit, the second photovoltaic cell unit and the intermediate layer as far as the surface of the first electrode, and a nitrogen concentration in the vicinity of a surface of a second electrode side of the second photovoltaic cell unit is higher than a nitrogen concentration of a region other than in the vicinity of the surface of the second photovoltaic cell unit.

A further aspect of the present invention is a manufacturing method for a photovoltaic device with a first photovoltaic cell unit and a second photovoltaic cell unit stacked on either side of a conductive intermediate layer, between a first electrode and a second electrode, comprising a first step of forming a channel passing through the first photovoltaic cell unit, the second photovoltaic cell unit and the intermediate layer as far as the surface of the first electrode, a second step of forming a PN junction at an end section of the intermediate layer, and a third step of forming the second electrode so as to be electrical connected to the first electrode via the channel.

According to the present invention it is possible to suppress reduction in characteristics due to contact between an intermediate layer and a rear surface electrode, in a photovoltaic device, without degrading characteristics of a photovoltaic cell unit.

### BRIEF DESCRIPTION OF THE DRAWINGS

FIG. 1 is a cross sectional schematic diagram showing the structure of a photovoltaic device of an embodiment of the present invention.

FIG. 2 is a diagram showing a manufacturing process for a photovoltaic device of an embodiment of the present invention.

FIG. 3 is a cross sectional schematic diagram showing the structure of a photovoltaic device of related art.

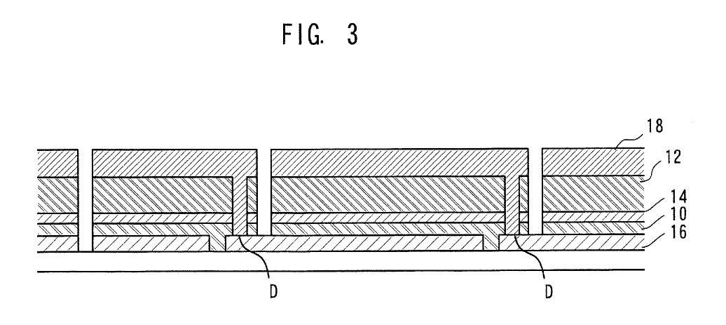

### DESCRIPTION OF PREFERRED EMBODIMENTS

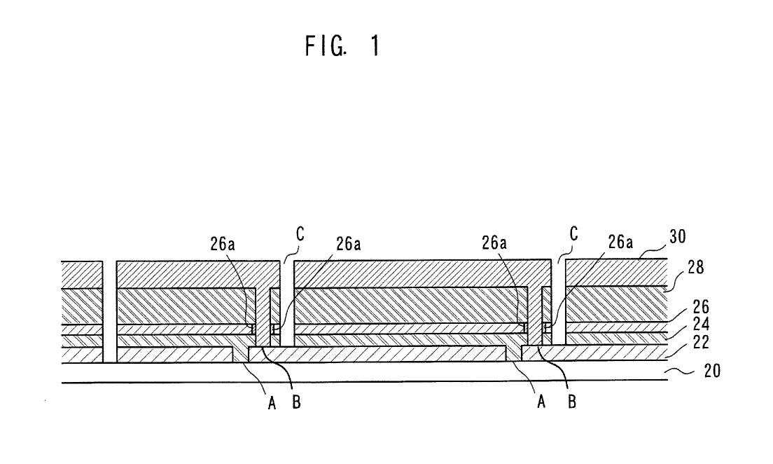

A photovoltaic device 100 of an embodiment of the present invention comprises a substrate 20, a surface electrode 22, a first photovoltaic cell unit 24, an intermediate layer 26, a second photovoltaic cell unit 28, and a rear surface electrode 30, as shown in the cross sectional drawing of FIG. 1.

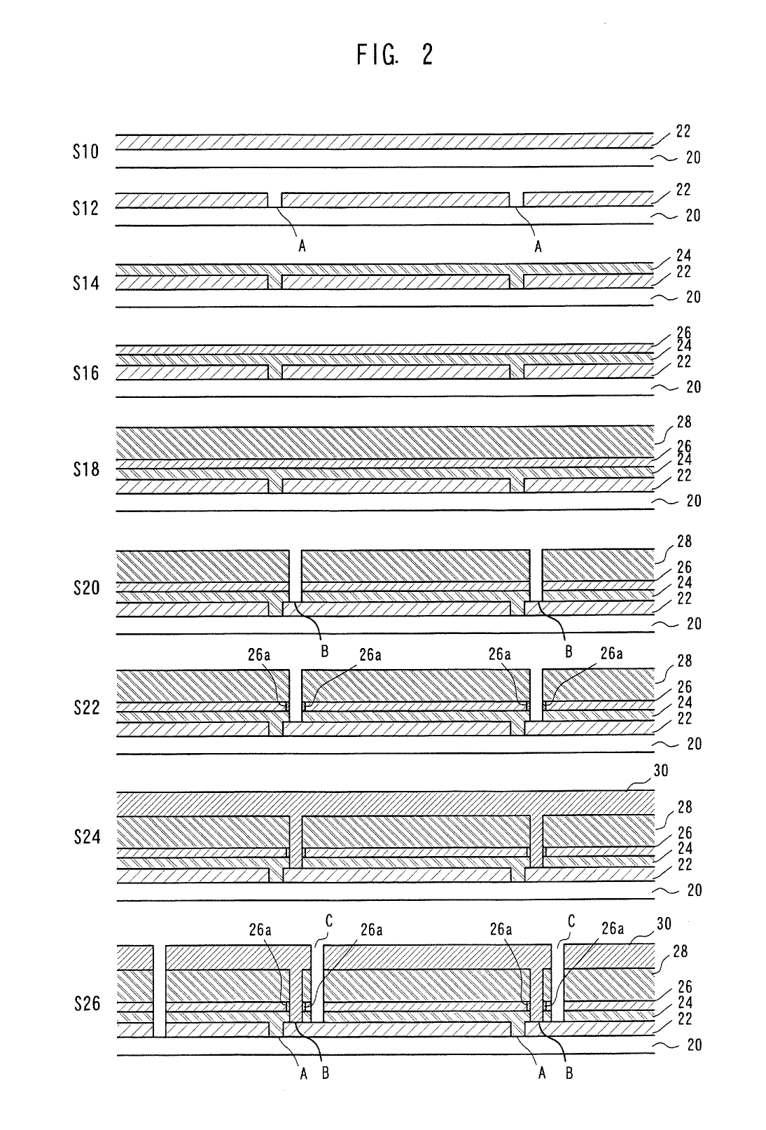

In the following, description will be given of a manufacturing method for the photovoltaic device 100, and the structure of the photovoltaic device 100, with reference to the manufacturing process diagram of FIG. 2. In FIG. 1 and FIG. 2, part of the photovoltaic device 100 is shown enlarged in order to clearly show the structure of the photovoltaic device 100, and the proportions of each section are shown varied.

In step S10, the surface electrode 22 is formed on the substrate 20. The substrate 20 is formed of a material having transparency. The substrate 20 can be made, for example, a glass substrate or plastic substrate etc. The surface electrode 22 is made a transparent conductive film having transparency. The surface electrode 22 can be made, for example, SnO₂, ZnO, TiO₂, SiO₂, In₂O₂ etc. F, Sn, Al, Fe, Ga, Nb etc. is doped into these metal-oxides. The surface electrode 22 is formed using, for example, a sputtering method or MOCVD method (thermal CVD). It is also preferable to provide unevenness (textured structure) on the surface of one or both of the substrate 20 and the surface electrode 22.

In step S12, a first isolation trench A is formed on the surface electrode 22. The isolation trench A is formed using laser processing for example. For example, the isolation trench A can be formed using an Nd:YAG laser having a wavelength of about 1064 nm and an energy density of 1×10⁵ W/cm². The line thickness of the isolation trench A is 10 μm or more and 200 μm or less.

In step S14, the first photovoltaic cell unit 24 is formed on the surface electrode 22. With this embodiment, the first photovoltaic cell unit 24 is an amorphous silicon photovoltaic cell. The first photovoltaic cell unit 24 is formed by laminating amorphous silicon films from the substrate 20 side in the order p-type, i-type, n-type. Film thickness of the i-layer of the first photovoltaic cell unit 24 is preferably 100 nm or more and 500 nm or less. The first photovoltaic cell unit 24 is formed using plasma-enhanced chemical vapor deposition (CVD). An example of film formation conditions for the first photovoltaic cell unit 24 is shown in Table 1.

In step S16, the intermediate layer 26 is formed on the first photovoltaic cell unit 24. The intermediate layer 26 is formed of a material having transparency. The intermediate layer 26 can be made, for example, ZnO, SiO₂, SnO₂, TiO₂, In₂O₃ etc. F, Sn, Al, Fe, Ga, Nb etc. can also be doped into these metal-oxides. Film thickness of the intermediate layer 26 is preferably 10 nm or more and 200 nm or less. The intermediate layer 26 can be formed using DC sputtering. An example of film formation conditions for the intermediate layer 26 is shown in table 1.

In step S18, the second photovoltaic cell unit 28 is formed on the intermediate layer 26. With this embodiment, the second photovoltaic cell unit 28 is a microcrystalline silicon photovoltaic cell. The second photovoltaic cell unit 28 is formed by laminating microcrystalline silicon films from the substrate 20 side in the order p-type, i-type, n-type. Film thickness of the i-layer of the second photovoltaic cell unit 28 is preferably 1000 nm or more and 5000 nm or less. The second photovoltaic cell unit 28 is formed using VHF plasma-enhanced chemical vapor deposition (CVD). An example of film formation conditions for the second photovoltaic cell unit 28 is shown in Table 1.

TABLE 1

| | substrate | gas flow | reaction | RF | film |
|---|---|---|---|---|---|
| | temperature | amount | pressure | power | thickness |
| | (° C.) | (sccm) | (Pa) | (W) | (nm) |
| P-layer | 180 | SiH₄: 300 | 106 | 10 | 15 |
| | | CH₄: 300 | | | |
| | | H₂: 2000 | | | |
| | | B₂H₆: 3 | | | |
| I-layer | 200 | SiH₄: 300 | 106 | 20 | 200 |
| | | H₂: 2000 | | | |
| N-layer | 180 | SiH₄: 300 | 133 | 20 | 30 |
| | | H₂: 2000 | | | |
| | | PH₃: 5 | | | |
| intermediate | 170 | Ar: 10 | 0.4 | 400 | 30 |
| layer | | | | | |
| (ZnO)106 | | | | | |
| P-layer | 180 | SiH₄: 10 | 106 | 10 | 30 |
| | | H₂: 2000 | | | |
| | | B₂H₆: 3 | | | |
| I-layer | 200 | SiH₄: 100 | 133 | 20 | 2000 |
| | | H₂: 2000 | | | |
| N-layer | 200 | SiH₄: 10 | 133 | 20 | 20 |
| | | H₂: 2000 | | | |
| | | PH₃: 5 | | | |

In step S20, a second isolation trench B is formed. The isolation trench B is formed passing through the second photovoltaic cell unit 28, the intermediate layer 26 and the first photovoltaic cell unit 24, so as to reach the surface electrode 22. The line thickness of the isolation trench B is 10 μm or more and 200 μm or less.

The isolation trench B is formed using laser processing, for example. Laser processing is preferably carried out using a wavelength of about 532 nm (second harmonic of a YAG laser), but is not limited to this. Energy density for the laser processing should be, for example, 1×10⁵ W/cm².

In step S22 plasma processing is carried out in an atmosphere that contains nitrogen (N). For example, plasma processing is preferably carried out in a nitrogen (N₂) or ammonia (NH₃) atmosphere. The plasma processing is preferably RF plasma processing. Pressure of a nitrogen containing gas at the time of plasma processing is preferably 50 Pa or more and 1000 Pa or less. Power density at the time of plasma processing is preferably 0.5 W/cm² or more and 100 W/cm² or less.

As a result of this plasma processing it is possible to raise the amount of nitrogen contained in the end sections 26a of the intermediate layer 26 that are exposed at the isolation trench B.

Also, amount of nitrogen contained in the surface of the n-layer of the second photovoltaic cell unit 28 as a result of the plasma processing is higher than the amount of nitrogen contained in other regions of the second photovoltaic cell unit 28, at least the amount of nitrogen contained the i-layer and the p-layer. For example, the nitrogen containing concentration of a region from the surface of the n-layer of the second photovoltaic cell unit 28 to a depth of 1000 nm is higher than the nitrogen containing concentration of regions at a depth of deeper than 1000 nm. It is possible to determine whether or not the processing of step S20 has been carried out from this distribution of nitrogen containing density. It is more difficult for nitrogen to contribute to degradation in the characteristics of a photovoltaic cell compared to oxygen, and further, nitrogen has only a small effect on an n-type silicon layer.

In step S24, the rear surface electrode 30 is formed on the second photovoltaic cell unit 28. The rear surface electrode 30 is preferably a stacked structure of a transparent conductive film and a metal film. The transparent conductive film can be made, for example, ZnO, SiO₂, SnO₂, TiO₂, etc., and using ZnO is further preferred. The metal film can use, for example, silver (Ag), aluminum (Al), gold (Au) etc., and it is more preferable to use silver (Ag) if reflectivity of the light used is taken into consideration. The rear surface electrode 30 is formed using, for example, a sputtering method.

The rear surface electrode 30 is embedded in the isolation trench B, and the rear surface electrode 30 and the surface electrode 22 are electrically connected inside the isolation trench B. Specifically, the rear surface electrode 30 is connected to the end sections 26a of the intermediate layer 26 in the isolation trench B.

In step S26, a third isolation trench C is formed. The isolation trench C is formed passing through the second photovoltaic cell unit 28, the intermediate layer 26 and the first photovoltaic cell unit 24, so as to reach the surface electrode 22. The isolation trench C is formed at a position sandwiching the isolation trench B between the isolation trench C and the isolation trench A. The line thickness of the isolation trench C is preferably 10 μm or more and 200 μor less. The isolation trench C can be formed using laser processing. For example, the isolation trench C can be formed using an Nd:YAG laser having a wavelength of about 532 nm (YAG laser second harmonic) and an energy density of 1×10⁵ W/cm².

Further, a channel separating a peripheral region and an electricity generating region is formed at the periphery of the photovoltaic device 100 by laser processing. As described above, with the photovoltaic device 100 of this embodiment the rear surface electrode 30 is connected to an end section 26a of the intermediate layer 26 having a high nitrogen content in the isolation trench. By injecting nitrogen the end section 26a of the intermediate layer 26 is considered to be made high resistance or p-type, and therefore constitutes a barrier with respect to carriers (electrons or positive holes) resulting from connection of the rear surface electrode 30 to the end section 26a, and it is possible to suppress leakage of current between the rear surface electrode 30 and the intermediate layer 26.

### EXAMPLE

A surface electrode 22 being an SnO₂ film having a textured structure was formed on a glass substrate 20, and an isolation trench A of 40 μm line thickness was formed. After that an amorphous silicon first photovoltaic cell unit 24 having an i-layer film thickness of 250 nm was formed.

After forming the first photovoltaic cell unit 24, a ZnO film having a film thickness of 50 nm and including aluminum as a dopant was formed as the intermediate layer 26. A microcrystalline silicon second photovoltaic cell unit 28 with an i-layer film thickness of 2000 nm was then formed.

After formation of the second photovoltaic cell unit 28, an isolation trench B of line width 50 μm was formed using the second harmonic of a Nd:YAG laser of wavelength 532 nm. After that, RF plasma processing is carried out in a nitrogen (N₂) or ammonia (NH₃) gas atmosphere, causing a higher nitrogen content in the end section 26a of the intermediate layer 26 than in other regions. After nitriding treatment, an aluminum doped ZnO film of film thickness 100 nm and a silver (Ag) film of film thickness 300 nm were sequentially formed as a rear surface electrode 30.

After formation of the rear surface electrode 30, an isolation trench C of line width 50 μm was formed using the second harmonic of a Nd:YAG laser of wavelength 532 nm. Also, a channel for separating a peripheral region and an electricity generating region of the photovoltaic device 100 is formed using the fundamental and second harmonic of an Nd:YAG laser of wavelengths 1064 nm and 532 nm.

### Comparative Example

A photovoltaic device that was the same as the above described example, other than the fact that nitriding using RF plasma treatment in an nitrogen (M₂) gas atmosphere was not carried out, was manufactured.

Current-voltage characteristics (I-V characteristics) for the photovoltaic device 100 manufactured in the above described example and the photovoltaic device produced in the above described comparative example were measured under conditions of AM 1.5, 100 mW/cm², 25° C. Measurement results are shown in table 2. In table 2, the characteristic for the photovoltaic device manufactured in the comparative example is shown as 1, and the characteristic for the photovoltaic device 100 manufactured in the example is shown normalized.

TABLE 2

| | | | short | | |
|---|---|---|---|---|---|
| | | | circuit | fill | |
| | | open voltage | current | factor | conversion |
| | | Voc | Isc | FF | efficiency η |
| example | N₂ | 1.011 | 1.011 | 1.049 | 1.128 |
| | processing | | | | |
| | NH₃ | 1.130 | 0.995 | 1.071 | 1.144 |
| | processing | | | | |
| comparative | | 1 | 1 | 1 | 1 |
| example | | | | | |

From the results of measurement the photovoltaic device 100 of this embodiment has improved conversion efficiency compared to the related art. In particular, for open voltage Voc and fill factor FF, the characteristic was improved whether plasma processing was carried out in either a nitrogen (N₂) or an ammonia (NH₃) atmosphere.

In this embodiment nitrogen has been used as a dopant for the intermediate layer 26, but other p-type dopants can also be considered to give similar effects. Similar effects can also be obtained using a metal-oxide film such as SiO₂ or TiO₂ etc., or other transparent conductive film, as the intermediate layer 26.

Also, with this embodiment description has been given of an amorphous silicon/microcrystalline silicon tandem structure for this film photovoltaic cell, but the scope of application of the present invention is not thus limited. Specifically, it can be considered that the same effects will be achieved as long as it is a photovoltaic device that uses a transparent conductive film as an intermediate layer. In particular, the same effects will be obtained if it is a silicon photovoltaic cell having silicon as a chief material, and provided with an intermediate layer formed from a transparent conductive film in a region adjacent to the silicon.

What is claimed is:

1. A photovoltaic device having a first photovoltaic cell unit and a second photovoltaic cell unit stacked on either side of a conductive intermediate layer, between a first electrode and a second electrode, wherein
the first electrode and the second electrode are electrically connected via a channel formed passing through the first photovoltaic cell unit, the second photovoltaic cell unit, and the intermediate layer as far as the surface of the first electrode, and
a PN junction is formed at an end section of the intermediate layer contacting the second electrode by adding dopant.

2. A photovoltaic device having a first electrode, a first photovoltaic cell unit, a conductive intermediate layer, a second photovoltaic cell unit, and a second electrode sequentially stacked, wherein
the first electrode and the second electrode are electrically connected via a channel formed passing through the first photovoltaic cell unit, the second photovoltaic cell unit, and the intermediate layer as far as the surface of the first electrode, and
a nitrogen concentration close to a surface of a second electrode side of the second photovoltaic cell unit is higher than a nitrogen concentration of regions other than close to the surface of the second photovoltaic cell unit.

3. The photovoltaic device of claim 1, wherein
the intermediate layer contains at least one of ZnO, SiO₂, SnO₂, TiO₂, and In₂O₃.

4. The photovoltaic device of claim 2, wherein
the intermediate layer contains at least one of ZnO, SiO₂, SnO₂, TiO₂, and In₂O₃.

5. The photovoltaic device of claim 1, wherein
the intermediate layer is ZnO, and
the dopant is at least one of N, P, As, Sb, Bi, Li, Na, K, Rb, Cs, Fr, Cu, Ag and Au.

6. A manufacturing method for a photovoltaic device having a first photovoltaic cell unit and a second photovoltaic cell unit stacked on either side of a conductive intermediate layer, between a first electrode and a second electrode, comprising
a first process of forming a channel passing through the first photovoltaic cell unit, the second photovoltaic cell unit, and the intermediate layer as far as the surface of the first electrode,
a second process of forming a PN junction at an end section of the intermediate layer by adding dopant to the intermediate layer that is exposed to the channel, and
a third process of forming the second electrode so as to be electrically connected to the first electride via the channel.

7. The manufacturing method for a photovoltaic device of claim 6, wherein
in the second process nitrogen is added to the intermediate layer as the dopant by carrying out plasma processing in a nitrogen or ammonia atmosphere.
